(19) United States
(12) Patent Application Publication
(10) Pub. No.: US 2022/0214610 A1
(43) Pub. Date: Jul. 7, 2022

(54) A PATTERNING DEVICE

(71) Applicant: ASML NETHERLANDS B.V., Veldhoven (NL)

(72) Inventors: Marie-Claire VAN LARE, Utrecht (NL); Frank Jan TIMMERMANS, Eindhoven (NL)

(73) Assignee: ASML NETHERLANDS B.V., Veldhoven (NL)

(21) Appl. No.: 17/607,701

(22) PCT Filed: Apr. 2, 2020
(86) PCT No.: PCT/EP2020/059366

§ 371 Date: Oct. 29, 2021

(30) Foreign Application Priority Data
May 2, 2019 (EP) 19172160.4

(51) Int. Cl. G03F 1/54; G03F 1/32

(52) U.S. Cl. CPC G03F 1/54; G03F 1/24; G03F 1/32

(57) ABSTRACT

A patterning device configured for use in a lithographic apparatus, the lithographic apparatus being configured to use radiation for imaging a pattern at the patterning device via projection optics onto a substrate. The patterning device including a first component for reflecting and/or transmitting the radiation, and a second component covering at least a portion of a surface of the first component and configured to at least partially absorb the radiation incident on the second component. The second component has a sidewall, wherein at least one part of the sidewall extends away from the first component at an angle, the angle being with respect to a plane parallel to the surface of the first component, and wherein the angle is less than 85 degrees.

### CROSS-REFERENCE TO RELATED APPLICATIONS

This application claims priority of EP application 19172160.4 which was filed on May 2, 2019 and which is incorporated herein in its entirety by reference.

### FIELD

The present invention relates to a patterning device.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

The use of standard attenuated phase shift patterning devices in a lithographic apparatus may result in only a relatively small % of the radiation intensity being diffracted into diffraction orders that are within the numerical aperture (NA) of the lithographic apparatus. Due to this, a relatively high % of the radiation is lost and this increases the required dose. Therefore, it may be desired to increase the % of radiation intensity diffracted into orders that are within the NA of the lithographic apparatus.

### SUMMARY

According to a first aspect of the invention, there is provided a patterning device configured for use in a lithographic apparatus, the lithographic apparatus being configured to use radiation for imaging a pattern at the patterning device via projection optics onto a substrate, the patterning device comprising: a first component for reflecting and/or transmitting the radiation, and a second component covering at least a portion of a surface of the first component and configured to at least partially absorb the radiation incident on the second component, wherein the second component comprises a sidewall, wherein at least one part of the sidewall extends away from the first component at an angle, the angle being with respect to a plane parallel to the surface of the first component, and wherein the angle is less than 85 degrees.

This may have an advantage that more radiation may be diffracted into the numerical aperture (NA) of the lithographic apparatus which may decrease the required dose of radiation. The shape of the second component may reduce an intensity of the radiation diffracted into higher orders as compared to an intensity of the radiation diffracted by a standard patterning device (with sidewalls perpendicular to the corresponding first component). This may improve throughput of the lithographic apparatus.

The second component may at least partially transmit the radiation incident on the second component so as to give the radiation emerging from the second component a phase shift relative to the radiation reflected off another portion of the first component not covered by the second component. The patterning device may be an attenuated phase shift patterning device.

The at least one part of the sidewall may be a substantial part of the sidewall.

The at least one part may be a majority part of the sidewall.

The sidewall may extend away from the first component at the angle at a substantially half way point of the sidewall.

The sidewall may have the angle at the substantially furthest point of the sidewall away from the first component.

At the substantially furthest point of the sidewall away from the first component, the sidewall may have a shape of a curve.

The curve may be a sinusoidal curve. This may have an advantage of providing an increased amount of radiation diffracted into the NA of the system when compared with other curves.

The sidewall may extend away from the first component at the angle over all of the sidewall.

The angle may be less than 70 degrees.

The angle may be 45 degrees.

The second component may have a further sidewall substantially opposite the sidewall of the second component, wherein at least one further part of the further sidewall may extend away from the first component at the angle.

The angle at which the further sidewall extends away from the first component may be different from the angle that the sidewall extends away from the first component.

The second component may have one or more additional sidewalls, wherein at least one additional part of the one or more additional sidewalls may extend away from the first component at the angle.

The angle at which the one or more additional sidewalls may extend away from the first component may be different from the angle that the sidewall extends away from the first component.

The patterning device may be at least one of a reflective patterning device, a transmissive patterning device, a binary patterning device, and an attenuated phase shift patterning device.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus and a radiation source;

FIG. 2a depicts a schematic diagram of a cross sectional side view of an attenuated phase shift patterning device in accordance with an embodiment of the invention;

FIG. 2b depicts a schematic diagram of a top view of an attenuated phase shift patterning device in accordance with the embodiment of FIG. 2a;

FIG. 3 depicts a schematic diagram of a cross sectional side view of an attenuated phase shift patterning device in accordance with another embodiment of the invention;

FIG. 4a depicts a schematic diagram of a cross sectional side view of a standard patterning device;

FIG. 4b depicts a schematic diagram of a cross sectional side view of an attenuated phase shift patterning device in accordance with another embodiment of the invention.

### DETAILED DESCRIPTION

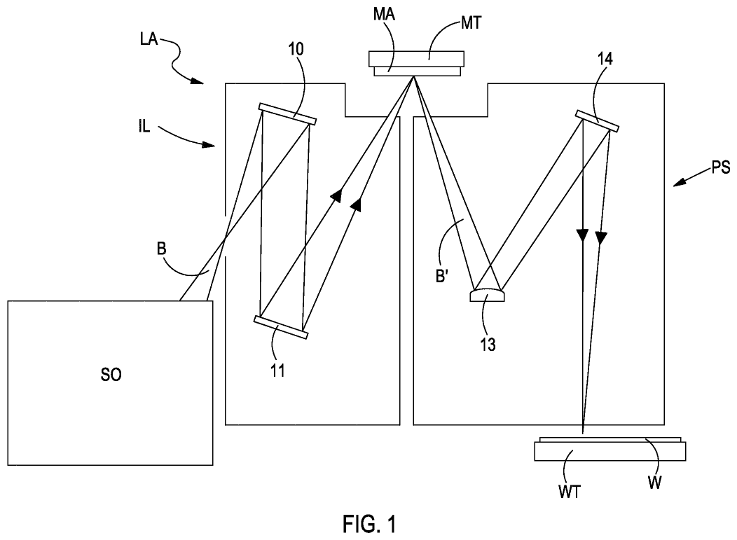

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13,14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO may be a laser produced plasma (LPP) source, a discharge produced plasma (DPP) source, a free electron laser (FEL) or any other radiation source that is capable of generating EUV radiation.

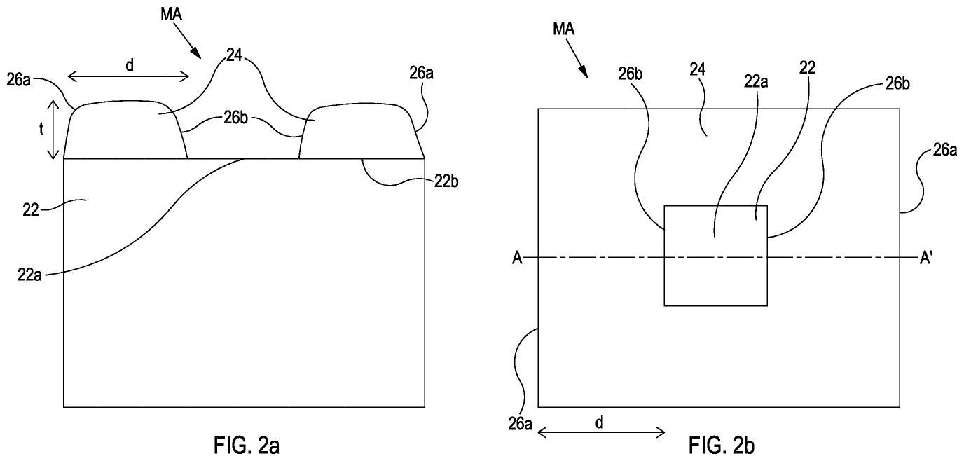

FIG. 2a shows a close up side view of part of the patterning device MA, which in this embodiment is an attenuated phase shift patterning device. More particularly, FIG. 2a shows a cross sectional side view of the attenuated phase shift patterning device MA taken through line A-A′ of FIG. 2b. A part of the attenuated phase shift patterning device MA is shown in FIG. 2b in a top view. It will be appreciated that FIGS. 2a and 2b show only part of the attenuated phase shift patterning device MA for clarity.

Phase shift patterning devices are photomasks that take advantage of the interference generated by phase differences to improve image resolution in photolithography. A phase shift patterning device relies on the fact that radiation passing through a transparent media (i.e. in this case being reflected from that media) will undergo a phase change as a function of its optical thickness.

The attenuated phase shift patterning device MA comprises a first component 22 for reflecting radiation and a second component 24 for reflecting radiation with a different phase with respect to the radiation reflected from the first component. The first component 22 comprises a standard multilayer mirror, e.g. alternating layers of molybdenum and silicon. The layers of the multilayer are not shown in FIG. 2a for simplicity. It will be appreciated that in other embodiments, the first component may have different numbers of layers and/or may comprise different materials.

Although embodiments directed to an attenuated phase shift patterning device are described, it will be appreciated that these embodiments are exemplary and the invention described is also applicable to other types of patterning devices. For example, other patterning devices called “binary masks” may be used. The name “binary” originates from the ideal picture where on the mask either all the radiation is absorbed (zero) or no light is absorbed (one). Patterning devices for EUV radiation may use tantalum as the base material.

The second component 24 is in a different layer from the first component 22, i.e. the second component 24 is located on the first component 22.

The second component 24 reflects a relatively small amount of radiation when compared with the first component 22. The radiation reflected from the second component 24 is not strong enough to create a pattern on the substrate W, but it can interfere with the radiation coming from the first component 22, with the goal of improving the contrast on the substrate W. The contrast may be considered to be the steepness, or sharpness, of the features formed in the image on the substrate W.

As can be seen in FIG. 2a and FIG. 2b, the second component 24 covers a portion (hereinafter referred to as a covered portion 22b) of the first component 22 except for an uncovered portion 22a of the surface of the first component 22 which forms a pattern. Radiation reflected from the uncovered portion 22a generates the patterned radiation beam B′ which forms a pattern in a target portion of the substrate W in the lithographic apparatus LA when in use. The covered portion 22b and the uncovered portion 22a together form a surface 23 of the first component 22. The second component 24 may be considered to surround the uncovered portion 22a of the first component 22, albeit that the second component 24 is in a different layer from the first component 22 and so it is actually the covered portions 22b that surround the uncovered portions 22a of the first component 22. The second component 24 may be considered to form a ring around the uncovered portion 22a of the first component 22. Although the area of the uncovered portion 22a of the first component 22 may be substantially a square or rectangle as viewed from above, in other embodiments, the uncovered portion may be any suitable shape and the second component may have a size and shape accordingly. The size of the uncovered portion 22a is related to the critical dimension (CD) of the feature to be printed on the substrate W. On the patterning device MA, the size of the uncovered portion 22a is the CD (on the substrate W) multiplied by the magnification factor in the lithographic apparatus LA. This may have a range of +/−30% (patterning device bias range). The magnification factor may be 4-8.

The second component 24 covers the covered portion 22b of the first component 22 which extends a distance d from the uncovered portion 22a of the first component 22. The optimal width will be feature and pitch dependent.

The second component 24 covers at least a portion (the covered portion 22b) of a surface of the first component 22 and is configured to at least partially absorb the radiation incident on the second component 24 and at least partially transmit the radiation incident on the second component 24 so as to give the radiation emerging from the second component 24 a phase shift relative to the radiation reflected off another portion (uncovered portion 22a) of the first component 22 not covered by the second component 24. The second component 24 has a width d which corresponds to the extent in the direction (taken parallel to the surface of the first component 22) of the covered portion 22b of the first component 22. The width d is depicted as a double arrow in FIGS. 2a and 2b.

Although only a single uncovered portion 22a is shown in FIG. 2a and FIG. 2b, (because these Figures only show part of the attenuated phase shift patterning device MA), it will be appreciated that the pattern may be formed of a plurality of uncovered portions 22a.

The terms cover/covered/covering as used within this description is intended to mean that the covering component is in a position such that radiation is at least partially blocked from being incident on the portion of the covered component underneath the covering component. That is, covering may be taken to encompass covering where the covering component is in direct contact with the covered component or not, i.e. another component may or may not be located between the component that is covering and the component being covered.

In this embodiment, the second component 24 comprises the material Ruthenium (Ru) with a thickness t (shown as a double arrow in FIG. 2). The thickness for Ru may preferably be 35 nm. The material Ru of the second component 24 may be considered to have replaced an absorbing material, e.g. a TaBN absorber, in a standard patterning device to form the attenuated phase shift patterning device MA. As will be appreciated, in other embodiments, different materials may be used instead of Ru. The thickness of the second component depends on the material composition, e.g. an alloy material containing Ru requires a different thickness from one containing only Ru. Typical thickness range for absorbers may be between 30 nm and 70 nm.

The attenuated phase shift patterning device MA may be used in the lithographic apparatus LA by reflecting radiation from the first component 22 of the attenuated phase shift patterning device MA, and reflecting radiation from the second component 24 of the attenuated phase shift patterning device MA. More particularly, reflecting radiation from the pattern comprising the uncovered portion 22a of the first component 22 and generating the patterned radiation beam B′. The effect of this is that the radiation reflected from the second component 24 has a different phase with respect to the radiation reflected from the first component 22 and provides a pattern on the substrate W with increased contrast.

The second component 24 has sidewalls 26a, 26b which are angled with respect to the first component 22. That is, they do not extend wholly perpendicularly to the surface 23 of the first component 22 as in a standard patterning device. The size of the second component 24 in the direction in which the distance d is taken decreases with increasing distance (thickness t) from the first component 22. The second component 24 may be considered to have a rounded corner or a curve at substantially the furthest point of the sidewalls 26a, 26b away from the first component 22. In some embodiments, the sidewalls may be completely curved (i.e. no straight sections) or one or more other parts of the sidewall may be curved.

The second component 24 having the shape as shown in FIG. 2a (i.e. a more rounded shape as compared to a standard patterning device with straight sidewalls) limits the amount of radiation that is diffracted into higher orders. The Fourier transform of this more-rounded shape will contain substantially less of the high-frequency components. Thus, more radiation will be diffracted into the NA of the lithographic apparatus LA which will decrease the required dose of radiation. The shape of the second component 24 will reduce an intensity of the radiation diffracted into higher orders as compared to an intensity of the radiation diffracted by a standard patterning device (with sidewalls perpendicular to the corresponding first component).

This will improve throughput of the lithographic apparatus LA (i.e. the number of substrates W that pass through the lithographic apparatus LA in a particular time) when compared to the standard patterning device having a second component made of Ru with straight sidewalls extending perpendicular to the first component. Furthermore, the patterning device MA having the second component 24 will improve throughput and yield (i.e. measure of substrates without defects) when compared to the standard patterning device having a second component made of Ta with straight sidewalls. This is because with more radiation the features may be printed with better quality in the resist on the substrate W.

Table 1 below compares the loss of photons for a standard 60 nm (thickness) Ta-based mask and a 35-nm (thickness) Ru-based attenuated phase shift mask (PSM). The Ru mask has a lower extinction coefficient and a thinner layer. Therefore, less radiation is lost upon a double pass through the mask absorber. The example here is given for dense contact holes (CHs) with 20% mask bias, so that 72% of the mask area is covered by absorber material.

Additionally, a large fraction of radiation is lost, since only the 0th and 1st order are within the NA (numerical aperture) of the system. The second column of table 1 shows the fraction of the radiation intensity that is distributed over orders that are outside the NA. This is larger for the Ru mask than for the Ta mask (more radiation goes into higher orders). 80% of the radiation goes into orders that are outside the NA for the Ru mask and therefore there would be a gain up to a factor 5 if all the radiation was diffracted within the NA. This is more than with the Ta mask where 70% of the radiation goes into orders that are outside the NA.

TABLE 1
Comparison of loss of photons for standard 60 nm
Ta-based mask and 35-nm Ru-based attenuated
PSM for 20 nm dense CHs on low NA EUV.

| | Lost in double | Lost in diffraction |
|---|---|---|
| | pass absorber, for | orders outside |
| | 72% mask coverage | NA |
| Ta | 0.69 | 0.7 |
| Ru | 0.53 | 0.8 |

The amount of radiation diffracted into the −1 order (which may also be outside the NA for off-axis illumination) will never be substantially lower than the amount of radiation in the +1 order and therefore it is theoretically not possible to reduce the amount of radiation into orders outside the NA to 0. In a rough upper limit the amount of radiation in +1, 0, and −1 would be equal and thus 33% of the radiation would be discarded. In the situation with the standard Ru mask, only 20% of the radiation was used (i.e. captured in the NA) whereas using the patterning device MA with the shape of the second component 24 means 67% of the radiation may be available for use. This means that the upper limit would give a dose gain of approximately factor 3 (i.e. 67% of the radiation being available for use is approximately 3×20% previously used). More generally, the patterning device MA provides a substantial gain in dose with respect to a standard patterning device with a second component made of Ru.

It will be appreciated that the described shape of the second component 24 of the patterning device MA may also be used with patterning devices having second components made from materials other than Ru. For example, these may be second components made from Tantalum or other absorbers, such as high k absorbers of e.g. Nickel or Cobalt, and other attenuated phase shift patterning device materials like Rhodium.

The shape of the second component 24 may be formed by isotropic plasma etching (pressure higher), depositing layers on top of discrete chunks of conventionally made absorber material with sharp edges (the sharpness will disappear with the additional layers deposited on top), etch away the material in between the sinusoidal bumps, and/or ion gunning.

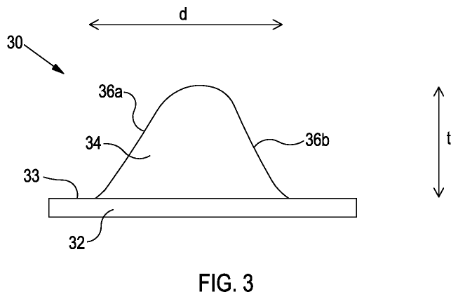

FIG. 3 shows a cross sectional side view of an embodiment of part of a patterning device 30. The part of the patterning device 30 shown in FIG. 3 corresponds to only part of patterning device MA of FIG. 2a. Thus, only part of a first component 32 and part of a second component 34 of the patterning device 30 is shown. It will be appreciated that the structure of the part of the second component 34 shown may be the same or different for other parts of the second component 34.

The second component 34 (made of Ru) has sidewalls 36a, 36b which are angled with respect to the first component 32 in a similar way as in FIG. 2a. That is, they do not extend wholly perpendicularly to a surface 33 of the first component 32 as in a standard patterning device. Similarly, the size of the second component 34 in the direction in which the distance d is taken decreases with increasing distance (thickness t) from the first component 32. The second component 34 may be considered to have a rounded corner or a curve at or near substantially the furthest point of the sidewalls 36a, 36b away from the first component 22. In the second component 34 of FIG. 3, these rounded corners or curves are more pronounced than in the second component 24 of FIG. 2a as there is not a flat surface between the curves as in second component 24 of FIG. 2a. That is, the second component 34 of FIG. 3 comes to a peak at a point where the sidewalls 36a, 36b meet. It is important that there is no sharp edges (e.g. 90 degree corners) which may cause unwanted diffraction.

The patterning device 30 also provides a gain in dose with respect to a standard patterning device having a second component made of Ru in a similar way as described above with respect to FIG. 2a.

In some embodiments, the curve of the sidewall at or near the substantially furthest point of the sidewall away from the first component may be a sinusoidal curve. This may provide an increased amount of radiation diffracted into the NA of the system when compared with other curves.

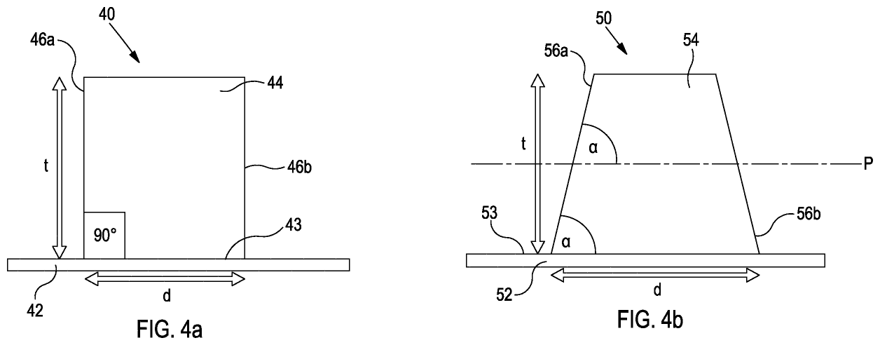

FIG. 4a shows a cross sectional side view of part of a standard patterning device 40 for comparison. The standard patterning device 40 has a first component 42 and a second component 44 (made of Ru) with straight sidewalls 46a, 46b extending substantially perpendicularly with respect to the first component 42 along the full thickness t of the second component 44. In other words, the sidewalls 46a, 46b extend away from the first component at 90 degrees to a plane parallel to a surface 43 of the first component 42 over all of the sidewalls 46a, 46b.

FIG. 4b shows a cross sectional side view of an embodiment of part of a patterning device 50. The patterning device 50 has a first component 52 and a second component 54 (made of Ru) with sidewalls 56a, 56b. For clarity, only sidewall 56a will now be referred to, but it will be appreciated that the features are also applicable to sidewall 56b or other sidewalls of the second component 54. In the patterning device 50, the sidewall 56a is straight but is angled with respect to the first component 52 in a similar way as in FIG. 2a. That is, the sidewall 56a does not extend wholly perpendicularly to a surface 53 of the first component 52 as in a standard patterning device. Similarly, the size of the second component 54 in the direction in which the distance d is taken decreases with increasing distance (thickness t) from the first component 52.

More particularly, the sidewall 56a of the second component 54 extends away from the first component 52 at an angle α, the angle α being with respect to the surface 53 of the first component 52, the angle α being less than 70 degrees. The angle being above 70 degrees may provide relatively little throughput gain. In this embodiment, the sidewall 56a extends away from the first component 52 at the angle α taken with respect to a plane P parallel to the surface 53 of the first component 52, the plane P being at a substantially half way point of the sidewall 56a. It will be appreciated that the plane P may be taken at any point along the sidewall 56a and as can be seen from FIG. 4b, the sidewall 56a extends away from the first component 52 at the angle α over all of the sidewall 56a. That is, the sidewall 56a maintains the same angle α with respect to planes parallel to the surface 53 of the first component 52 along the full length of the sidewall 56a.

The patterning device 50 also provides a gain in dose with respect to a standard patterning device having a second component made of Ru in a similar way as described above with respect to FIG. 2a.

It will be appreciated that, in other embodiments, the sidewall of the second component may be different, i.e. have a different shape or a different angle with respect to a plane parallel to the surface of the first component over some or all of the length of the sidewall. For example, only a part of the sidewall may have the angle α(e.g. which is less than 70 degrees). In some embodiments, the part of the sidewall extending at the angle α may extend over a substantial part of the sidewall. In some embodiments, the part of the sidewall extending at the angle α may extend over a majority part of the sidewall, i.e. over more than half of the sidewall. The part of the sidewall extending at the angle α may be at or near substantially the furthest point of the sidewall away from the first component.

It will be appreciated that, in other embodiments, the angle α may be less than 85 degrees. In other embodiments, the angle α may be 45 degrees. The optimal angle will depend on the thickness of the second component (which as mentioned may be anywhere between 30 nm and 70 nm) and will also depend on the feature size and pitch (which can also cover a large range of sizes). It will also be appreciated that the sidewall may have different angles at different parts of the sidewall. For example, the sidewall may have a part with a 90 degree angle close to the first component, then have a part with a 45 degree angle (e.g. at a substantially half way point of the sidewall) and then another part further from the first component with a 90 degree angle. As another example, the sidewall may have a part with a 45 degree angle, then have a part with a 90 degree angle, then have a part with a 45 degree angle and so on. Therefore, e.g. the substantial part (or majority part) of the sidewall extending at the angle α(e.g. 45 degrees) need not be continuous and may have sections where the sidewall does not have the angle α.

In some embodiments, the sidewall 56a and the sidewall 56b (i.e. a further sidewall opposite the sidewall 56a) may have the same angle α. More particularly, a further part of the further sidewall may extend away from the first component 52 at the same angle α. However, in other embodiments, the sidewalls 56a, 56b may extend away at different angles.

In some embodiments, the second component 54 may have one or more additional sidewalls (not shown), these sidewalls may form a different part of the second component 54 and/or may extend in perpendicular directions to the sidewalls 56a, 56b of the second component 54. The additional sidewall(s) may have the same angle α or may have a different angle to the sidewall 56a (and the sidewall 56b). More particularly, an additional part of one or more of the additional sidewalls may extend away from the first component 52 at the same angle α or a different angle.

Although the above description has been concerned with a reflective phase shift patterning device (i.e. for use with EUV radiation), the structure of the second component described above may also be used in a transmissive patterning device (such as for use with DUV radiation). For example, in this case, the first component may be transmissive. The transmissive patterning device may be a binary patterning device.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A patterning device configured for use in a lithographic apparatus, the lithographic apparatus being configured to use radiation for imaging a pattern at the patterning device via projection optics onto a substrate, the patterning device comprising:
a first component configured to reflect and/or transmit the radiation, and
a second component covering at least a portion of a surface of the first component and configured to at least partially absorb the radiation incident on the second component,
wherein the second component comprises a sidewall, wherein at least one part of the sidewall extends away from the first component at an angle, the angle being with respect to a plane parallel to the surface of the first component, and wherein the angle is less than 85 degrees.

2. The patterning device of claim 1, wherein the at least one part of the sidewall is a substantial part of the sidewall.

3. The patterning device of claim 1, wherein the at least one part is a majority part of the sidewall.

4. The patterning device of claim 1, wherein the sidewall extends away from the first component at the angle at a substantially half way point of the sidewall.

5. The patterning device of claim 1, wherein the sidewall has the angle at the substantially furthest point of the sidewall away from the first component.

6. The patterning device of claim 1, wherein at the substantially furthest point of the sidewall away from the first component, the sidewall has a shape of a curve.

7. The patterning device of claim 6, wherein the curve is a sinusoidal curve.

8. The patterning device of claim 1, wherein the sidewall extends away from the first component at the angle over all of the sidewall.

9. The patterning device of claim 1, wherein the angle is less than 70 degrees.

10. The patterning device of claim 1, wherein the angle is 45 degrees.

11. The patterning device of claim 1, wherein the second component has a further sidewall substantially opposite the sidewall of the second component, wherein at least one further part of the further sidewall extends away from the first component at the angle.

12. The patterning device of claim 11, wherein the angle at which the further sidewall extends away from the first component is different from the angle that the sidewall extends away from the first component.

13. The patterning device of claim 1, wherein the second component has one or more additional sidewalls, wherein at least one additional part of the one or more additional sidewalls extends away from the first component at the angle.

14. The patterning device of claim 13, wherein the angle at which the one or more additional sidewalls extend away from the first component is different from the angle that the sidewall extends away from the first component.

15. The patterning device of claim 1, wherein the patterning device is a reflective patterning device, a transmissive patterning device, a binary patterning device, and/or an attenuated phase shift patterning device.

16. A patterning device configured for use in a lithographic apparatus, the lithographic apparatus configured to use radiation for imaging a pattern at the patterning device via projection optics onto a substrate, the patterning device comprising:
a first component configured to reflect and/or transmit the radiation, and
a second component covering at least a portion of a surface of the first component and configured to reflect and/or transmit at least some of the radiation incident on the second component,
wherein the second component comprises a sidewall and at least part of the sidewall has a shape of a curve extending away from the first component with respect to a plane parallel to the surface of the first component.

17. The patterning device of claim 16, wherein the curve is a sinusoidal curve.

18. The patterning device of claim 16, wherein at least a further part of the sidewall extends away from the first component at an angle, the angle being with respect to the plane, and wherein the angle is less than 85 degrees.

19. The patterning device of claim 18, wherein the at least further part is a majority part of the sidewall.

20. The patterning device of claim 18, wherein the angle is less than 70 degrees.
